(19) United States
(12) Patent Application Publication
(10) Pub. No.: US 2009/0286490 A1
(43) Pub. Date: Nov. 19, 2009

(54) OSCILLATOR CIRCUIT, TRANSCEIVER, AND METHOD FOR GENERATING OSCILLATORY SIGNAL

(76) Inventor: Yuan-Hung Chung, Hsinchu County (TW)

Correspondence Address: NORTH AMERICA INTELLECTUAL PROPERTY CORPORATION, P.O. BOX 506, MERRIFIELD, VA, 22116, US

(21) Appl. No.: 12/123,456

(22) Filed: May 19, 2008

(51) Int. Cl. H04B 1/40; H03B 21/00

(52) U.S. Cl. 455/75; 331/42

(57) ABSTRACT

An oscillator circuit, a transceiver, and a method for generating an oscillatory signal are provided to avoid the VCO pulling effect. The oscillator circuit includes an oscillator, a frequency multiplier, a frequency divider, and a mixer module. The oscillator is utilized for generating a first signal having a first frequency. The frequency multiplier is coupled to the oscillator, and utilized for generating a second signal according to the first signal, wherein the second signal has a second frequency. The frequency divider is coupled to the oscillator, and utilized for generating a third signal according to the first signal, wherein the third signal has a third frequency. The mixer module is coupled to the frequency multiplier and the frequency divider, and utilized for mixing the second signal and the third signal to generate the oscillatory signal having an output frequency being not a harmonic of the first frequency.

### BACKGROUND

The present invention relates to an oscillator circuit, and more particularly, to an oscillator circuit utilized in a transceiver, and a method for generating an oscillatory signal having a properly adjusted output frequency.

In general, a TX of a transceiver having a traditional oscillator circuit has a VCO pulling effect. The cause for the VCO pulling effect is usually due to the TX output signal coupled to the VCO, and the most probable cause is that the VCO frequency is a harmonic of the TX output frequency. The VCO pulling effect will cause performance degradation, such as phase noises, EVM, etc.

### SUMMARY OF THE INVENTION

It is therefore one of the objectives of the present invention to provide an oscillator circuit utilized in a transceiver, and a method for generating an oscillatory signal having a properly adjusted output frequency, so as to solve the above problems.

In accordance with an embodiment of the present invention, an oscillator circuit for generating an oscillatory signal is disclosed. The oscillator circuit includes an oscillator, a frequency multiplier, a frequency divider, and a mixer module. The oscillator is utilized for generating a first signal having a first frequency. The frequency multiplier is coupled to the oscillator, and utilized for generating a second signal according to the first signal, wherein the second signal has a second frequency. The frequency divider is coupled to the oscillator, and utilized for generating a third signal according to the first signal, wherein the third signal has a third frequency. The mixer module is coupled to the frequency multiplier and the frequency divider, and utilized for mixing the second signal and the third signal to generate the oscillatory signal having an output frequency not being a harmonic of the first frequency.

In accordance with an embodiment of the present invention, a transceiver is further disclosed. The transceiver includes a local oscillator circuit for generating an oscillatory signal and a controlling circuit. The oscillator circuit includes an oscillator, a frequency multiplier, a frequency divider, and a mixer module. The oscillator is utilized for generating a first signal having a first frequency. The frequency multiplier has a programmable multiplier and is coupled to the oscillator, and utilized for generating a second signal according to the first signal, wherein the second signal has a second frequency. The frequency divider has a programmable divisor and is coupled to the oscillator, and utilized for generating a third signal according to the first signal, wherein the third signal has a third frequency. The mixer module is coupled to the frequency multiplier and the frequency divider, and is utilized for mixing the second signal and the third signal to generate the oscillatory signal having an output frequency being not a harmonic of the first frequency. The controlling circuit is coupled to the local oscillator circuit, and utilized for setting the programmable multiplier and the programmable divisor.

In accordance with an embodiment of the present invention, a method for generating an oscillatory signal is yet further disclosed. The method includes generating a first signal having a first frequency by an oscillator, generating a second signal according to the first signal by a frequency multiplier (the second signal having a second frequency), generating a third signal according to the first signal by a frequency divider (the third signal having a third frequency), and mixing the second signal and the third signal by a mixer module to generate the oscillatory signal having an output frequency being not a harmonic of the first frequency.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a simplified block diagram of a transceiver in accordance with an embodiment of the present invention.

FIG. 2 shows a simplified block diagram of the local oscillator circuit of the transceiver in FIG. 1 in accordance with a first embodiment of the present invention.

FIG. 3 shows a simplified block diagram of the local oscillator circuit of the transceiver in FIG. 1 in accordance with a second embodiment of the present invention.

FIG. 4 is a flowchart showing a method for generating an oscillatory signal having a properly adjusted output frequency applied to a transceiver in accordance with the operation schemes of the local oscillator circuit of the present invention.

### DETAILED DESCRIPTION

Certain terms are used throughout the following description and the claims to refer to particular system components. As one skilled in the art will appreciate, manufacturers may refer to a component by different names. This document does not intend to distinguish between components that differ in name but not function. In the following discussion and in the claims, the terms “include”, “including”, “comprise”, and “comprising” are used in an open-ended fashion, and thus should be interpreted to mean “including, but not limited to . . . ” The terms “couple” and “coupled” are intended to mean either an indirect or a direct electrical connection. Thus, if a first device couples to a second device, that connection may be through a direct electrical connection, or through an indirect electrical connection via other devices and connections.

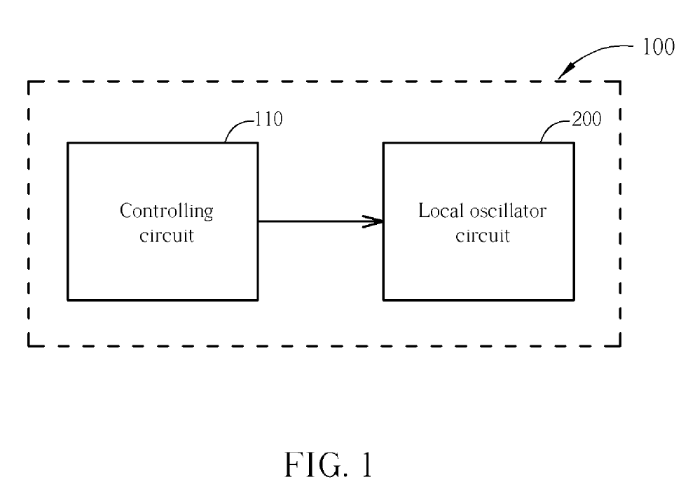

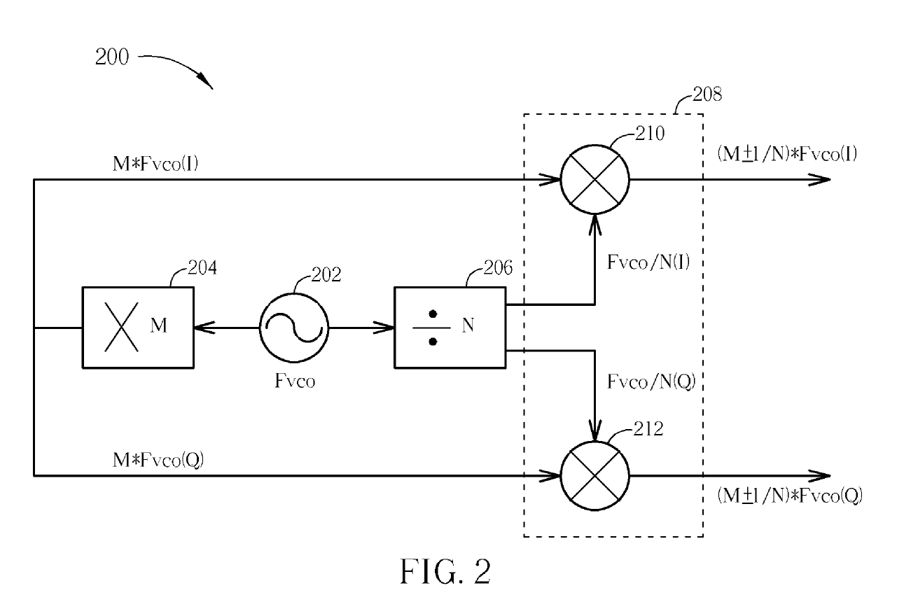

Please refer to FIG. 1 and FIG. 2. FIG. 1 shows a simplified block diagram of a transceiver 100 in accordance with an embodiment of the present invention. The transceiver 100 includes a local oscillator circuit 200 for generating an oscillatory signal and a controlling circuit 110 coupled to the local oscillator circuit 200. FIG. 2 shows a simplified block diagram of the local oscillator circuit 200 of the transceiver 100 in accordance with a first embodiment of the present invention. As shown in FIG. 2, the local oscillator circuit 200 includes an oscillator 202, a frequency multiplier 204, a frequency divider 206, and a mixer module 208. The oscillator 202 is utilized for generating a first signal having a first frequency Fvco.

The frequency multiplier 204 has a programmable multiplier M and is coupled to the oscillator 202, and is utilized for generating a second signal according to the first signal, wherein the second signal has a second frequency M*Fvco. The frequency divider 206 has a programmable divisor N and is coupled to the oscillator 202, and is utilized for generating a third signal according to the first signal, wherein the third signal has a third frequency Fvco/N. The mixer module 208 is coupled to the frequency multiplier 204 and the frequency divider 206, and is utilized for mixing the second signal and the third signal to generate the oscillatory signal, wherein the oscillatory signal has an output frequency (M±1/N)*Fvco. In addition, please note that the controlling circuit 110 in FIG. 1 is utilized for setting the programmable multiplier M and the programmable divisor N.

In the first embodiment, the oscillator 202 includes an in-phase (I) output and a quadrature (Q) output, and the frequency multiplier 204 includes an I input coupled to the I output of the oscillator 202, a Q input coupled to the Q output of the oscillator 202, an I output, and a Q output. The frequency divider 206 includes an I input coupled to the I output of the oscillator 202, a Q input coupled to the Q output of the oscillator 202, an I output, and a Q output, and the mixer module 208 includes a first mixer 210 and a second mixer 212 each having a first input, a second input and an output. The I output from the frequency multiplier 204 is coupled to the first input of the first mixer, and the Q output from the frequency multiplier 204 is coupled to the first input of the second mixer. The I output from the frequency divider 206 is coupled to the second input of the first mixer, and the Q output from the frequency divider 206 is coupled to the second input of the second mixer.

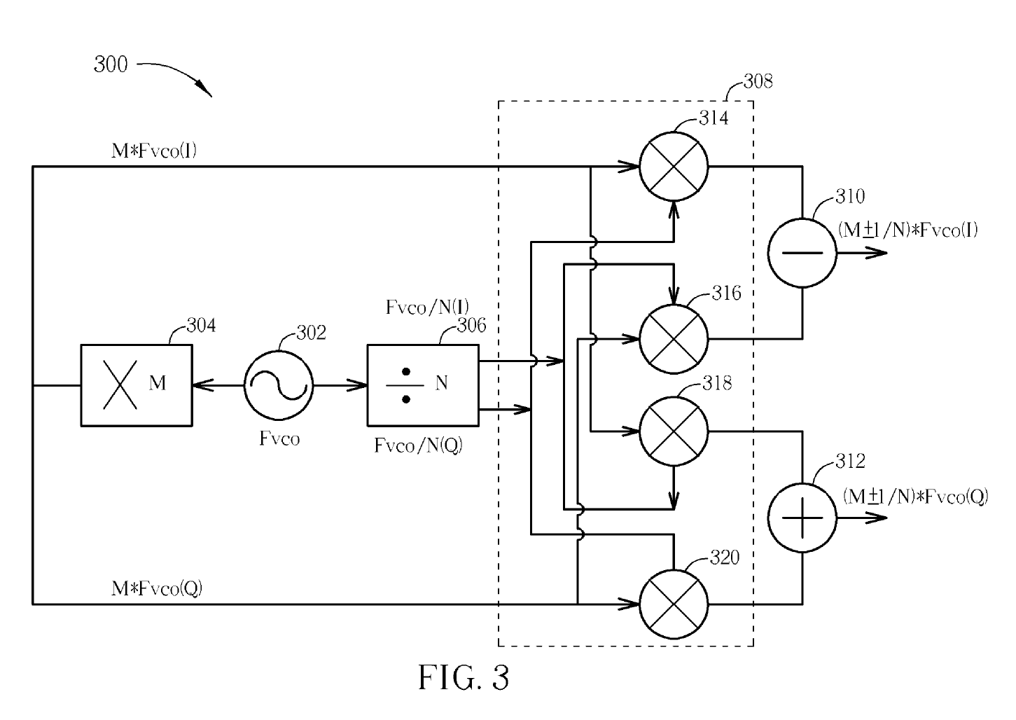

Please refer to FIG. 3. FIG. 3 shows a simplified block diagram of the local oscillator circuit 200 of the transceiver 1 00 in accordance with a second embodiment of the present invention. As shown in FIG. 3, the local oscillator circuit 200 includes an oscillator 302, a frequency multiplier 304, a frequency divider 306, a mixer module 308, a subtractor 310, and an adder 312. The oscillator 302 is utilized for generating a first signal having a first frequency Fvco.

The frequency multiplier 304 has a programmable multiplier M and is coupled to the oscillator 302, and utilized for generating a second signal according to the first signal, wherein the second signal has a second frequency M*Fvco. The frequency divider 306 has a programmable divisor N and is coupled to the oscillator 302, and is utilized for generating a third signal according to the first signal, wherein the third signal has a third frequency Fvco/N. The mixer module 308 is coupled to the frequency multiplier 304 and the frequency divider 306, and is utilized for mixing the second signal and the third signal to generate the oscillatory signal, wherein the oscillatory signal has an output frequency (M±1/N)*Fvco. The subtractor 310 and the adder 312 are coupled to the mixer module 308. In addition, please note that the controlling circuit 110 in FIG. 1 is utilized for setting the programmable multiplier M and the programmable divisor N.

In the second embodiment, the oscillator 302 includes an in-phase (I) output and a quadrature (Q) output; the frequency multiplier 304 includes an I input coupled to the I output of the oscillator 302, a Q input coupled to the Q output of the oscillator 302, an I output, and a Q output. The frequency divider 306 includes an I input coupled to the I output of the oscillator 302, a Q input coupled to the Q output of the oscillator 302, an I output, and a Q output. The mixer module 308 includes first, second, third, and fourth mixers 314, 316, 318, 320, each having a first input, a second input and an output. The I output from the frequency multiplier 304 is coupled to the first inputs of the first and third mixers 314, 318, and the Q output from the frequency multiplier 304 is coupled to the first inputs of the second and fourth mixers 316, 320. The Q output from the frequency divider 306 is coupled to the second inputs of the first and fourth mixers 314, 320, and the I output from the frequency divider 306 is coupled to the second inputs of the second and third mixers 316, 318. The outputs of the first and second mixers 314, 316 are coupled together via the subtractor 310, and the outputs of the third and fourth mixers are coupled together via the adder 312.

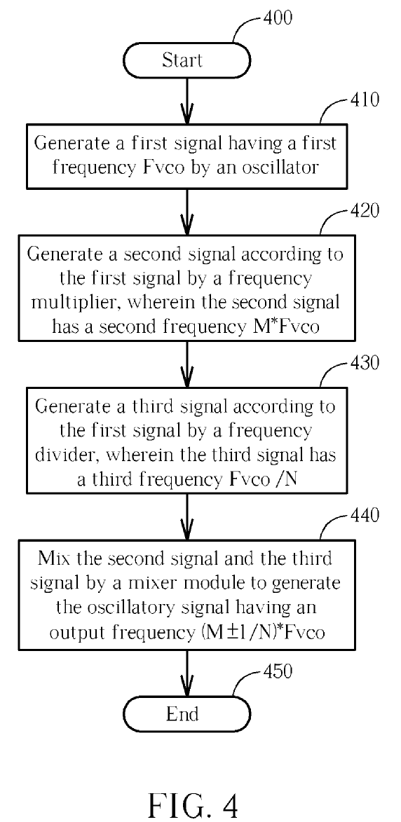

Please refer to FIG. 4. FIG. 4 is a flowchart showing a method for generating an oscillatory signal having a properly adjusted output frequency applied to a transceiver in accordance with the operation schemes of the local oscillator circuit 200 in the above embodiments of the present invention. Provided that as long as substantially the same result is achieved, the steps of the process flowchart need not be in the exact order shown and need not be contiguous; that is, other steps can be intermediate. The method applied to the transceiver according to the present invention includes the following steps:
Step 400: Start.
Step 410: Generate a first signal having a first frequency Fvco by an oscillator.
Step 420: Generate a second signal according to the first signal by a frequency multiplier, wherein the second signal has a second frequency M*Fvco.
Step 430: Generate a third signal according to the first signal by a frequency divider, wherein the third signal has a third frequency Fvco/N.
Step 440: Mix the second signal and the third signal by a mixer module to generate the oscillatory signal having an output frequency (M+1/N)*Fvco.
Step 450: End.

Briefly summarized, since the first frequency Fvco (i.e., the VCO frequency) is not a harmonic of the output frequency (M±1/N)*Fvco, the VCO pulling effect can be avoided by utilizing the oscillator circuit, the transceiver, and the method of the prevent invention.

Those skilled in the art will readily observe that numerous modifications and alterations of the device and method may be made while retaining the teachings of the invention.

What is claimed is:

1. An oscillator circuit for generating an oscillatory signal, the oscillator circuit comprising:
an oscillator, for generating a first signal having a first frequency;
a frequency multiplier, coupled to the oscillator, for generating a second signal according to the first signal, the second signal having a second frequency;
a frequency divider, coupled to the oscillator, for generating a third signal according to the first signal, the third signal having a third frequency; and
a mixer module, coupled to the frequency multiplier and the frequency divider, for mixing the second signal and the third signal to generate the oscillatory signal having an output frequency being not a harmonic of the first frequency.

2. The oscillator circuit of claim 1, wherein the oscillator comprises an in-phase (I) output and a quadrature (Q) output; the frequency multiplier comprises an I input coupled to the I output of the oscillator, a Q input coupled to the Q output of the oscillator, an I output, and a Q output; the frequency divider comprises an I input coupled to the I output of the oscillator, a Q input coupled to the Q output of the oscillator, an I output, and a Q output; and the mixer module comprises first, second, third, and fourth mixers each having a first input, a second input and an output, the I output from the frequency multiplier being coupled to the first inputs of the first and third mixers, the Q output from the frequency multiplier being coupled to the first inputs of the second and fourth mixers, the Q output from the frequency divider being coupled to the second inputs of the first and fourth mixers, and the I output from the frequency divider being coupled to the second inputs of the second and third mixers, the outputs of the first and second mixers being coupled together, and the outputs of the third and fourth mixers being coupled together.

3. The oscillator circuit of claim 2, further comprising a subtractor to combine the outputs of the first and second mixers, and an adder to combine the outputs of the third and fourth mixers.

4. The oscillator circuit of claim 1, being a local oscillator circuit in a transceiver.

5. A transceiver, comprising:
a local oscillator circuit for generating an oscillatory signal, the local oscillator circuit comprising:
an oscillator, for generating a first signal having a first frequency;
a frequency multiplier, having a programmable multiplier and being coupled to the oscillator, for generating a second signal according to the first signal, the second signal having a second frequency;
a frequency divider, having a programmable divisor and being coupled to the oscillator, for generating a third signal according to the first signal, the third signal having a third frequency; and
a mixer module, coupled to the frequency multiplier and the frequency divider, for mixing the second signal and the third signal to generate the oscillatory signal having an output frequency being not a harmonic of the first frequency; and
a controlling circuit, coupled to the local oscillator circuit, for setting the programmable multiplier and the programmable divisor.

6. The transceiver of claim 5, wherein the oscillator comprises an in-phase (I) output and a quadrature (Q) output, the frequency multiplier comprises an I input coupled to the I output of the oscillator, a Q input coupled to the Q output of the oscillator, an I output, and a Q output, the frequency divider comprises an I input coupled to the I output of the oscillator, a Q input coupled to the Q output of the oscillator, an I output, and a Q output, and the mixer module comprises first, second, third, and fourth mixers each having a first input, a second input and an output, the I output from the frequency multiplier being coupled to the first inputs of the first and third mixers, the Q output from the frequency multiplier being coupled to the first inputs of the second and fourth mixers, the Q output from the frequency divider being coupled to the second inputs of the first and fourth mixers, and the I output from the frequency divider being coupled to the second inputs of the second and third mixers, the outputs of the first and second mixers being coupled together, and the outputs of the third and fourth mixers being coupled together.

7. The transceiver of claim 6, wherein the local oscillator circuit further comprises a subtractor to combine the outputs of the first and second mixers, and an adder to combine the outputs of the third and fourth mixers.

8. A method for generating an oscillatory signal, the method comprising:
generating a first signal having a first frequency by an oscillator;
generating a second signal according to the first signal by a frequency multiplier, the second signal having a second frequency;
generating a third signal according to the first signal by a frequency divider, the third signal having a third frequency; and
mixing the second signal and the third signal by a mixer module to generate the oscillatory signal having an output frequency being not a harmonic of the first frequency.
